(19) United States
(12) Patent Application Publication
(10) Pub. No.: US 2017/0256292 A1
(43) Pub. Date: Sep. 7, 2017

(54) MEMORY ARRAY POWER REDUCTION THROUGH REDUCED SUPPLY VOLTAGE

(71) Applicant: Apple Inc., Cupertino, CA (US)

(72) Inventor: Edward M. McCombs, Austin, TX (US)

(21) Appl. No.: 15/058,631

(22) Filed: Mar. 2, 2016

(51) Int. Cl. G11C 5/14; G11C 7/12; G11C 7/06

(52) U.S. Cl. CPC G11C 5/14; G11C 7/062; G11C 7/12

(57) ABSTRACT

Systems, apparatuses, and methods for implementing a storage array with a voltage regulator circuit. An integrated circuit (IC) may include a storage array, periphery logic, and a voltage regulator circuit coupled to an array power supply and a periphery power supply; the latter may operate at any of several periphery operating voltages according to respective power modes of operation. One or more of the periphery operating voltages may be less than a threshold array operating voltage that is required by the storage array for read or write access during an active mode of storage array operation. The voltage regulator circuit may generate, dependent on a selected power mode, a regulated array power supply that operates at a voltage that satisfies the threshold array operating voltage and is less than an operating voltage of the array power supply. The regulated power supply may reduce overall power consumption of the storage array.

### BACKGROUND

Technical Field

Embodiments described herein relate to the field of processors and more particularly, to techniques for reducing power consumption in memory arrays.

Description of the Related Art

A processor is generally hardware circuitry designed to execute the instructions defined in a particular instruction set architecture implemented by the processor, for the purpose of implementing a wide variety of functionality specified by software developers. To implement a given architecture, processors typically include a variety of types of circuits. For example, a processor may include functional units that are designed to operate on data to produce arithmetic, logical, or other types of results. Functional units and other execution-related processor logic may be implemented using combinational logic gates that implement various Boolean functions, often in combination with state elements such as registers, latches, flip-flops, or the like. A processor may also include storage arrays that are primarily designed to store data rather than process or transform it; storage arrays may be used within processors to implement various types of caches, register files, queues, buffers, or other types of storage structures.

As semiconductor fabrication processes evolve, it has become possible to design combinational logic circuits that operate at lower voltages than in the past, correspondingly reducing the power consumed by such circuits. For a variety of reasons, voltage requirements of storage arrays have not declined to the same degree as combinational logic external to such arrays. Consequently, storage arrays tend to be significant power consumers within integrated circuits.

Power requirements tend to substantially influence the cost and performance of a system that employs a particular integrated circuit design. For example, excessive power requirements may in turn require more expensive circuit packaging and cooling. In mobile applications, power consumption directly affects battery life and total device run time. Accordingly, the power requirements of storage arrays within an integrated circuit may have far-reaching implications for system cost and performance.

### SUMMARY

Systems, apparatuses, and methods for implementing a storage array with a voltage regulator circuit that provides a regulated array power supply at a reduced voltage are contemplated.

In various embodiments, an integrated circuit may include a storage array that in turn includes bit cells, bit lines configured to read and write various bit cells, and sense amplifiers coupled to the bit lines. The integrated circuit may further include periphery logic coupled to the storage array, and a voltage regulator circuit coupled to an array power supply and a periphery power supply, the latter configured to selectively operate at any of several periphery operating voltages according to a respective power mode of operation. One or more of the periphery operating voltages may be less than a threshold array operating voltage that is required by the storage array for read or write access during an active mode of storage array operation.

The voltage regulator circuit may be configured to generate, dependent on a selected power mode of operation, a regulated array power supply that operates at a voltage that satisfies the threshold array operating voltage and is less than an operating voltage of the array power supply. The regulated array power supply may be coupled to at least a portion of the storage array.

In various embodiments, a system may include a memory and one or more processors coupled to the memory. Each of the one or more processors may include a storage array, periphery logic coupled to the storage array, and a voltage regulator circuit.

In a manner similar to that described above, the voltage regulator circuit may be configured to generate, dependent upon a selected power mode of operation, a regulated array power supply that operates at a voltage that satisfies a threshold array operating voltage of the storage array and is less than an operating voltage of an array power supply.

Various embodiments of a method are also contemplated. The method may include generating, by a voltage regulator circuit coupled to an array power supply and a periphery power supply, a regulated array power supply coupled to at least a portion of a storage array; and performing, by the storage array, read or write accesses using the regulated array power supply during an active mode of storage array operation. The generating may be dependent on a selected one of several power modes of operation. The periphery power supply may selectively operate at any of a number of periphery operating voltages according to a respective one of the power modes of operation. One or more of the periphery operating voltages may be less than a threshold array operating voltage required by the storage array for read or write access during the active mode of storage array operation. The regulated array power supply may operates at a voltage that satisfies the threshold array operating voltage and is less than an operating voltage of the array power supply.

### BRIEF DESCRIPTION OF THE DRAWINGS

The above and further advantages of the methods and mechanisms may be better understood by referring to the following description in conjunction with the accompanying drawings, in which:

FIG. 1 is a block diagram illustrating an embodiment of an integrated circuit.

FIG. 2 is a block diagram of an embodiment of a storage array.

FIGS. 3-5 are block diagrams illustrating various embodiments of a storage array that includes a voltage regulator circuit.

FIGS. 6-7 are circuit diagrams illustrating various embodiments of a voltage regulator circuit.

FIGS. 8-9 are a generalized flow diagram illustrating embodiments of methods of operation of a storage array including a voltage regulator circuit.

FIG. 10 is a block diagram of an embodiment of a system.

### DETAILED DESCRIPTION OF EMBODIMENTS

In the following description, numerous specific details are set forth to provide a thorough understanding of the methods and mechanisms presented herein. However, one having ordinary skill in the art should recognize that the various embodiments may be practiced without these specific details. In some instances, well-known structures, components, signals, computer program instructions, and techniques have not been shown in detail to avoid obscuring the approaches described here. It will be appreciated that for simplicity and clarity of illustration, elements shown in the figures have not necessarily been drawn to scale. For example, the dimensions of some of the elements may be exaggerated relative to other elements.

This specification includes references to “an embodiment.” The appearance of the phrase “in an embodiment” in different contexts does not necessarily refer to the same embodiment. Particular features, structures, or characteristics may be combined in any suitable manner consistent with this disclosure. Furthermore, as used throughout this application, the word “may” is used in a permissive sense (i.e., meaning “having the potential to”), rather than the mandatory sense (i.e., meaning “must”). Similarly, the words “include,” “including,” and “includes” mean including, but not limited to.

Terminology. The following paragraphs provide definitions and/or context for terms found in this disclosure (including the appended claims):

“Comprising.” This term is open-ended. As used in the appended claims, this term does not foreclose additional structure or steps. Consider a claim that recites: “A system comprising a processor . . . .” Such a claim does not foreclose the system from including additional components (e.g., a display, a memory controller).

“Configured To.” Various units, circuits, or other components may be described or claimed as “configured to” perform a task or tasks. In such contexts, “configured to” is used to connote structure by indicating that the units/circuits/components include structure (e.g., circuitry) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. §112(f) for that unit/circuit/component. Additionally, “configured to” can include generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

“Based On.” As used herein, this term is used to describe one or more factors that affect a determination. This term does not foreclose additional factors that may affect a determination. That is, a determination may be solely based on those factors or based, at least in part, on those factors. Consider the phrase “determine A based on B.” While B may be a factor that affects the determination of A, such a phrase does not foreclose the determination of A from also being based on C. In other instances, A may be determined based solely on B. “Dependent on” may be employed as a synonym for “based on.”

“In Response To.” As used herein, this term is used to describe causality of events or conditions. For example, in the phrase “B occurs in response to A,” there is a cause-and-effect relationship in which A causes B to occur. It is noted that this phrase does not entail that A is the only event that causes B to occur; B may also occur in response to other events or conditions that may be independent of or dependent on A. Moreover, this phrase does not foreclose the possibility that other events or conditions may also be required to cause B to occur. For example, in some instances, A alone may be sufficient to cause B to happen, whereas in other instances, A may be a necessary condition, but not a sufficient one (such as in the case that “B occurs in response to A and C”).

“Each.” With respect to a plurality or set of elements, the term “each” may be used to ascribe some characteristic to all the members of that plurality or set. But absent language to the contrary, use of “each” does not foreclose the possibility that other instances of the element might not include the characteristic. For example, in the phrase “a plurality of widgets, each of which exhibits property A,” there must be at least two (and possibly arbitrarily many) widgets that exhibit property A. But without more, this does not foreclose the possibility of an additional widget, not a member of the plurality, that does not exhibit property A. In other words, absent language to the contrary, the term “each” does not refer to every possible instance of an element, but rather every element in a particular plurality or set.

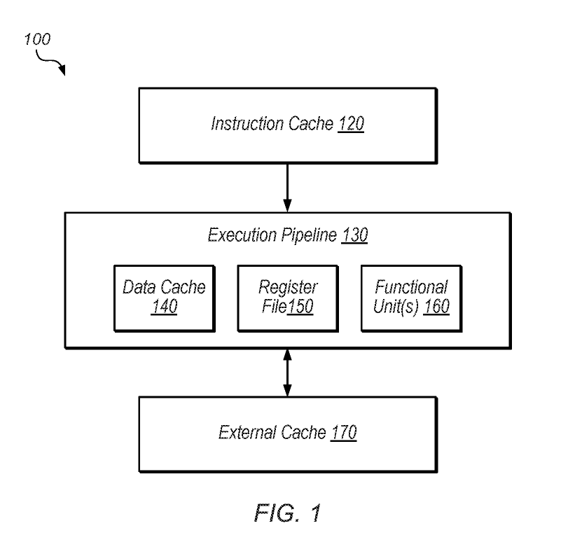

Turning now to FIG. 1, a block diagram of one embodiment of a portion of an integrated circuit 100 is shown. In various embodiments, integrated circuit 100 may correspond to a general-purpose processor, an embedded processor, a graphics processor, a digital signal processor (DSP), or any other type of processor that is generally capable of operating on digital data. In the illustrated embodiment, integrated circuit 100 includes an instruction cache 120 coupled to an execution pipeline 130, which is in turn coupled to an external cache 170. As shown in FIG. 1, execution pipeline 130 further includes a data cache 140, a register file 150, and one or more functional units 160.

As a preliminary matter, it is noted that FIG. 1 is intended to illustrate several components that tend to be common to many digital integrated circuit designs. These components are illustrated at a high level of abstraction in order to facilitate the discussion of more particular features below. It is noted that integrated circuit 100 may include numerous features in addition to those shown, and may be organized in any suitable fashion beyond that shown here.

Instruction cache 120 may generally be configured to store instructions for execution by execution pipeline 130. For example, instruction cache 120 may be configured to fetch instructions from external storage (such as system memory) well in advance of when those instructions are expected to be executed, in order to hide the latency of accessing external storage. In various embodiments, instruction cache 120 may be configured according to any suitable cache architecture (e.g., direct-mapped, set-associative, etc.). Integrated circuit 100 may also include other circuitry related to instruction fetch and issuance, such as instruction decode and/or issue logic, which may be included within instruction cache 120 or elsewhere. In some embodiments, instruction cache 120 or another component of integrated circuit 100 may include branch prediction circuitry, predication circuitry, or other features relating to the conditional or speculative execution of instructions.

Execution pipeline 130 may generally be configured to execute instructions issued from instruction cache 120 to perform various operations. Such instructions may be defined according to an instruction set architecture (ISA), such as the x86 ISA, the PowerPC™ ISA, the Arm™ ISA, or any other suitable architecture.

In the illustrated embodiment, execution pipeline 130 includes data cache 140. Similar to instruction cache 120, data cache 140 may provide temporary storage for data retrieved from another, slower memory within a memory hierarchy. Instructions executed by execution pipeline 130 may access the contents of data cache 140 through explicit load or store instructions, or via other instructions that implicitly reference load/store operations in combination with other operations, depending on the characteristics of the implemented ISA. Data cache 140 may be organized as direct-mapped, set-associative, or using any other suitable cache geometry, and may implement single or multiple read and write ports.

Register file 150, also an illustrated component of execution pipeline 130, may be configured as architecturally-visible registers and/or registers distinct from those specified by the ISA. For example, an ISA may specify a set of registers (such as a set of 32 64-bit registers denoted R0 through R31, for example) that executable instructions may specify as the source of data operands. However, in order to implement performance-improving schemes such as register renaming, register file 150 may implement a larger number of physical registers than those defined by the ISA, allowing architectural registers to be remapped to physical registers in ways that help resolve certain types of data dependencies between instructions. Accordingly, register file 150 may be substantially larger than the minimum set of architecturally-visible registers defined by the ISA. Moreover, register file 150 may be implemented in a multi-ported fashion in order to support multiple concurrent read and write operations by different, concurrently-executing instructions. In various embodiments, logic to perform register renaming, port scheduling and/or arbitration, or any other aspects relating to the operation of register file 150 may be included within register file 150 itself or within another unit.

Functional unit(s) 160 may be configured to carry out many of the various types of operations specified by a given ISA. For example, functional unit(s) 160 may include combinatorial logic configured to implement various arithmetic and/or logical operations, such as integer or floating-point arithmetic, Boolean operations, shift/rotate operations, address arithmetic for load/store operations, or any other suitable functionality. In some embodiments, execution pipeline 130 may include multiple different functional units 160 that differ in terms of the types of operations they support. For example, execution pipeline 130 may include a floating point unit configured to perform floating-point arithmetic, one or more integer arithmetic/logic units (ALUs) configured to perform integer arithmetic and Boolean functions, a graphics unit configured to implement operations particular to graphics processing algorithms, a load/store unit configured to execute load/store operations, and/or other types of units.

External cache 170 may be configured as an intermediate cache within a memory hierarchy. For example, external cache 170 may be a second-level cache interposed between external system memory and the first-level instruction cache 120 and data cache 140. Although often larger and slower than first-level caches, external cache 170 may nevertheless be substantially faster to access than external random-access memory (RAM), and its inclusion may improve the average latency experience by a typical load or store operation. External cache 170 may be configured according to any suitable cache geometry, which may differ from the geometries employed for instruction cache 120 and/or data cache 140. In some embodiments, still further caches may be interposed between external cache 170 and system memory.

Many of the elements discussed above share the common characteristic that they may include storage arrays that are configured to store substantial quantities of data for subsequent retrieval and use. For example, although their configurations may differ to suit their different roles, each of instruction cache 120, data cache 140, and external cache 170 may be configured to store data on the order of kilobytes, megabytes, or more. Similarly, although register file 150 may have different bandwidth requirements than the various caches, it nevertheless may be implemented as a storage array of the general organization to be discussed shortly. Finally, functional unit(s) 160 may include data structures such as buffers (e.g., load/store buffers) that lend themselves to implementation as storage arrays.

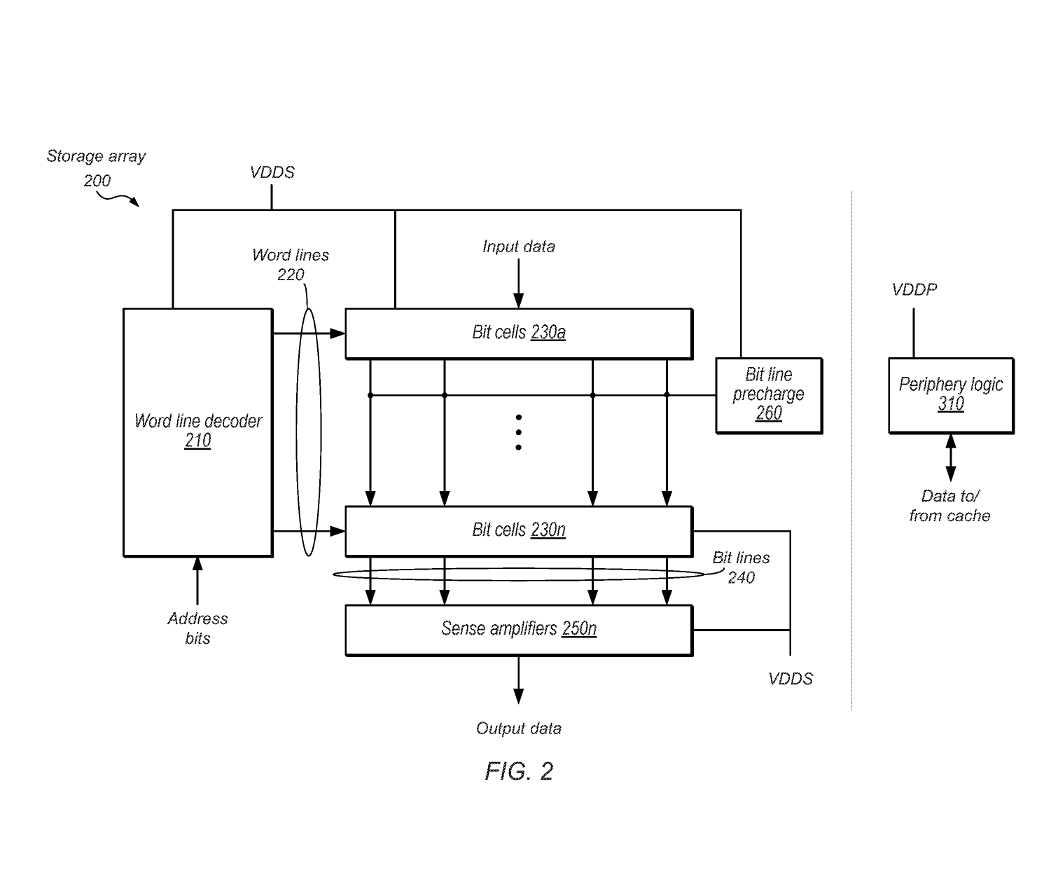

FIG. 2 illustrates an embodiment of a storage array 200 that, with suitable modifications, may be used in a variety of ways within integrated circuit 100, including within the types of elements just discussed. First, the general organization of storage array 200 will be described. Subsequently, supply voltage characteristics of storage array 200 will be discussed, particularly with respect to periphery logic 310 (which, as discussed in greater detail below, may refer to logic circuitry external or internal to storage array 200 that is designed to operate at a different voltage than storage array 200).

In the illustrated embodiment, storage array 200 includes a word line decoder 210 coupled to receive address bits and decode them into a number of word lines 220. For example, in an embodiment of storage array 200 that includes 128 word lines 220, seven bits of the memory address for a load or store operation may be decoded to select a particular one of the 128 word lines 220.

Each of word lines 220 may be coupled to a corresponding set of bit cells 230a-n. Collectively, bit cells 230a-n are coupled to receive input data, and are also coupled to a set of bit lines 240, which are in turn coupled to a set of sense amplifiers 250 and are also coupled to a bit line precharge circuit 260. Sense amplifiers 250 may provide, as output data, the data stored in the bit cells 230 that are selected by a particular word line 220. It is noted that in some embodiments, storage array 200 may include further elements that process the output data before it is provided as the output of storage array 200 itself. For example, in a set-associative cache, a way selection may be performed on the basis of a tag comparison.

It is noted that the number of word lines 220, bit cells 230, bit lines 240, and sense amplifiers 250 may vary in different embodiments according to factors such as the size of storage array 200 and its performance requirements. Moreover, although the elements of FIG. 2 have been arranged to facilitate a logical discussion of their operation, the physical arrangement of these elements need not necessarily correspond to what is shown.

In some embodiments, each individual one of bit cells 230 may be designed to store a single bit of information. A conventional six-transistor (6T) bit cell implementation may be employed, in which four transistors are arranged as a pair of cross-coupled inverters that form a storage element, the true and complement nodes of which are coupled to true and complement bit lines 240 via two additional transistors under the control of one of word lines 220. However, other configurations may also be employed for bit cells 230, including multi-ported bit cells and bit cells capable of storing multiple bits of information.

As just noted, in some embodiments, each bit cell 230 within a row controlled by a single word line 220 may be coupled to a pair of bit lines 240, such that storage array 200 may include twice as many physical bit lines 240 as bit cells 230 per row.

Under the assumption that only one word line 220 is active at a time during a read or write access, a single pair of bit lines 240 may be wired across corresponding bits in each row of bit cells 230. In a multi-ported implementation of storage array 200, a separate pair of bit lines 240 may be provided for each port of bit cells 230.

Because the size of storage array 200 tends to be heavily influenced by the size of individual bit cells 230, there may exist a strong design incentive to keep bit cells 230 compact. However, the smaller the device size employed within bit cells 230, the weaker the ability of each bit cell 230 to develop a voltage differential across a pair of bit lines 240 when the cell is being read. This may be partially compensated for by bit line precharge circuit 260, which precharges each of bit lines 240 (i.e., both true and complement bit lines) to a known voltage prior to performing an array access. But given a small device size and the comparably large capacitance presented by bit lines 240, a bit cell 230 may only be capable of developing a voltage differential of, for example, several tens or hundreds of millivolts across the true and complement pair of bit lines 240 to which it is coupled. Accordingly, sense amplifiers 250 are configured to amplify the small voltage differential present on bit lines 240 during a read operation and convert it to a level that can be used to drive downstream logic. (Although the use of differential signaling across pairs of bit lines 240 has been discussed above, single-ended bit line implementations are possible and contemplated.)

As noted above, decreasing semiconductor device geometries generally enable fabrication of devices that are capable of operating at lower supply voltages, reducing overall circuit power requirements. However, in order to meet design performance and/or reliability goals, it may be necessary to drive various elements of storage array 200 at voltages that are higher than the voltages that other circuits might require. This situation is illustrated in FIG. 2 through the use of two distinct power supplies: an array power supply, denoted VDDS, is shown coupled to various elements of storage array 200, while a periphery power supply, denoted VDDP, is shown coupled to periphery logic 310. Typically, VDDS operates at a substantially higher voltage than VDDP, such as 25-50% higher than VDDP or even greater. (One of ordinary skill will recognize that the VDDS/VDDP terminology may be used to refer either to the power supply as a physical entity or to the voltage at which the power supply operates, the precise connotation being clear from context.)

Generally speaking, periphery logic 310 may denote any type of circuitry within integrated circuit 100 that is external to storage array 200. For example, periphery logic 310 may include datapath logic, control logic, state elements, or other types of circuits, and may be located within execution pipeline 130 or elsewhere within integrated circuit 100. It is noted that in some embodiments, periphery logic 310 may also include elements located within storage array 200 that are capable of being driven by VDDP. For example, in some embodiments, storage array 200 may include decoders or other circuitry that does not require the higher VDDS voltage.

It may often be the case that the operating voltage of array power supply VDDS is selected to satisfy the most stringent performance scenario specified for integrated circuit 100, which may be the highest frequency of operation at which integrated circuit 100 is expected to operate. (Generally speaking, higher operating frequencies require higher voltages to ensure reliable operation.) However, it may also be the case that under certain conditions, storage array 200 may be capable of operating at operating voltages that are lower than the operating voltage of array power supply VDDS. Specifically, in some embodiments, storage array 200 may be capable of performing array read or write accesses, during an active mode of operation, at a threshold operating voltage that is less than the operating voltage of array power supply VDDS. (As used herein, an “active mode of operation” of a storage array, during which read or write accesses may be performed, is distinct from a “retention mode of operation,” during which a storage array may retain the state of data already stored in the array, but does not exhibit the full read/write capability with respect to that data that is available in the active mode.) For example, the operating voltage of array power supply VDDS at full operating frequency might be, e.g., between about 1-2 volts, and in some embodiments, about 1.5 volts. However, at a lower operating frequency, storage array 200 might be capable of operating at a threshold operating voltage as low as, e.g., 200 millivolts-1 volt, and in some embodiments, about 800 millivolts.

The fact that storage array 200 may be configured to operate at threshold array operating voltages lower than the full operating voltage of array power supply VDDS may present opportunities to improve the power consumption of storage array 200. Preliminarily, in various embodiments, integrated circuit 100 may provide a number of different modes of operation, at different combinations of voltage and frequency, that represent different tradeoffs between device performance and power consumption.

More particularly, in some embodiments, periphery power supply VDDP may be configured to operate at any one of several different periphery operating voltages, depending on which one of several power modes of operation is currently selected. For example, periphery logic 310 may be capable of operating at three different pairs of operating voltage and frequency: (VDDP1, F1), (VDDP2, F2), and (VDDP3, F3), ranging from lowest voltage and frequency (e.g., several hundred millivolts at several hundred MHz) to highest voltage and frequency (e.g., at or over one volt at 1 GHz or higher), respectively. Any number of modes specifying corresponding operating voltages and frequencies may be employed.

Thus, the periphery operating voltage of periphery power supply VDDP may vary according to different power modes of operation. Moreover, it may be the case that for one or more of those power modes of operation, it is possible to operate storage array 200 at a threshold operating voltage that is lower than the operating voltage of array power supply VDDS. Taking advantage of these circumstances to permit storage array 200 to operate at a lower voltage may substantially reduce power consumption while meeting the performance specifications (e.g., operating frequency) defined by the selected power mode of operation.

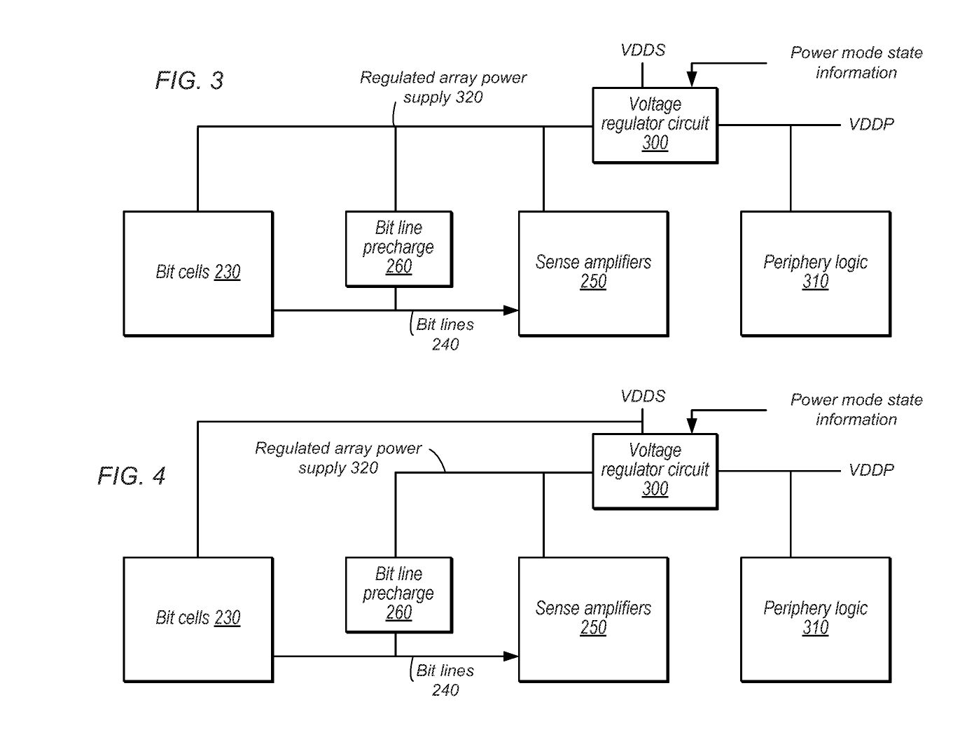

FIG. 3 illustrates an embodiment of storage array 200 that is configured for reduced-power operation. In particular, FIG. 3 illustrates a voltage regulator circuit 300 that is coupled both to periphery power supply VDDP and array power supply VDDS. Voltage regulator circuit 300 is further coupled to receive power mode state information indicative of a selected power mode of operation in which periphery power supply VDDP is currently operating.

In the illustrated embodiment, only a portion of the elements of storage array 200 are shown, it being understood that storage array 200 may include additional or different elements. Moreover, it is contemplated that in some embodiments, storage array 200 may include one or more elements that are coupled to periphery power supply VDDP rather than array power supply VDDS. Still further, it is contemplated that in some embodiments, each of several storage arrays 200 within integrated circuit 100 may have its own dedicated instance of voltage regulator circuit 300 that is designed to meet the particular characteristics of an individual storage array 200. In other embodiments, however, a single instance of voltage regulator circuit 300 may be coupled to multiple distinct storage arrays 200.

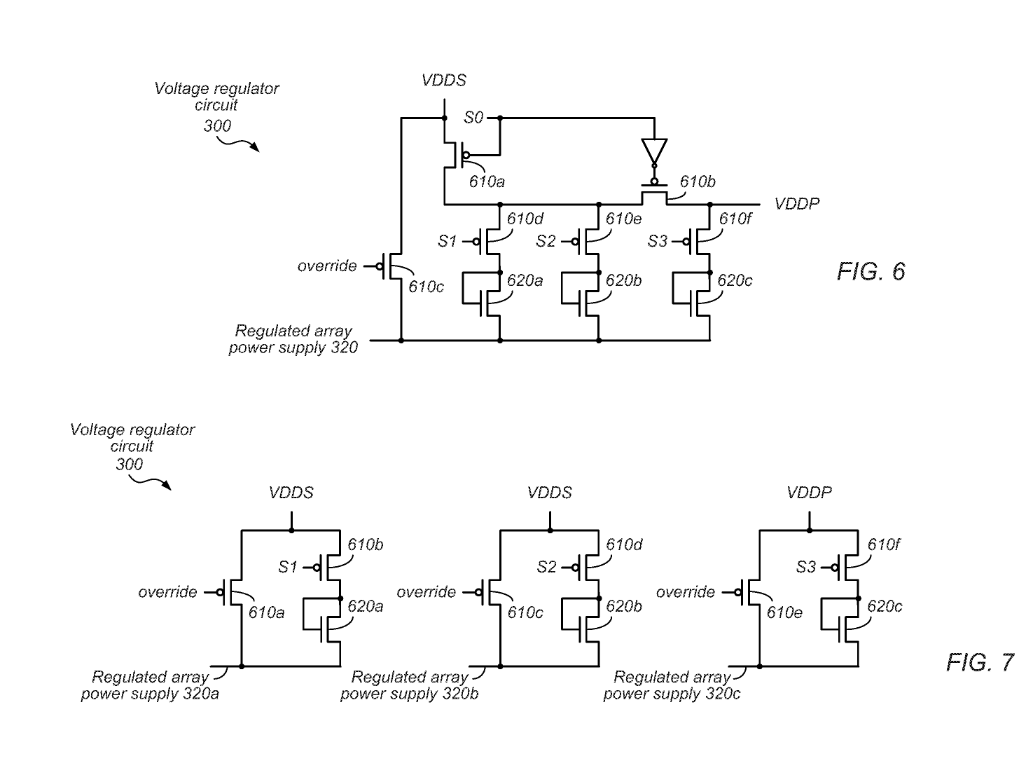

As described in greater detail below in conjunction with the description of FIG. 6, dependent upon the selected power mode of operation, voltage regulator circuit 300 is configured to generate a regulated array power supply 320 that, in the embodiment of FIG. 3, is coupled to each of bit cells 230, bit line precharge circuit 260, and sense amplifiers 250. As noted previously, bit line precharge circuit 260 may be configured to precharge bit lines 240 to a known voltage prior to performing a read operation within storage array 200. In the illustrated embodiment, regulated array power supply 320 may operate at a voltage that satisfies the threshold array operating voltage, but which is less than the operating voltage of array power supply VDDS, thus potentially reducing the power consumption of storage array 200.

It is noted that different elements within storage array 200 may require different threshold voltages to operate during the active mode of operation of storage array 200. For example, in some embodiments, bit cells 230 may be most sensitive to the effects of decreased operating voltage, and may therefore exhibit the highest threshold operating voltage of the three elements shown. By contrast, bit lines 240 may be relatively insensitive in terms of operating voltage, permitting bit cell precharge circuit 260 to precharge them to a relatively lower threshold voltage. In various embodiments, sense amplifiers 250 may exhibit a threshold voltage that is comparable to that of bit lines 240 or intermediate between bit lines 240 and bit cells 230. In the embodiment of FIG. 3, because a single regulated array power supply 320 is provided, its operating voltage may be chosen to be the highest threshold voltage required by any element within storage array 200.

FIG. 4 illustrates another embodiment of storage array 200, differing from that of FIG. 3 primarily in that regulated array power supply 320 is coupled to sense amplifiers 250 and bit cell precharge circuit 260, whereas bit cells 230 are coupled to array power supply VDDS. As noted above, because bit cells 230 may exhibit a higher threshold voltage than the remaining elements, decoupling bit cells 230 from regulated array power supply 320 may enable regulated array power supply 320 to operate at a lower voltage than the configuration shown in FIG. 3. In some circumstances, this configuration may enable lower power consumption than the case in which regulated array power supply 320 is coupled to drive multiple elements of storage array 200 at the higher threshold voltage that may be required by bit cells 230.

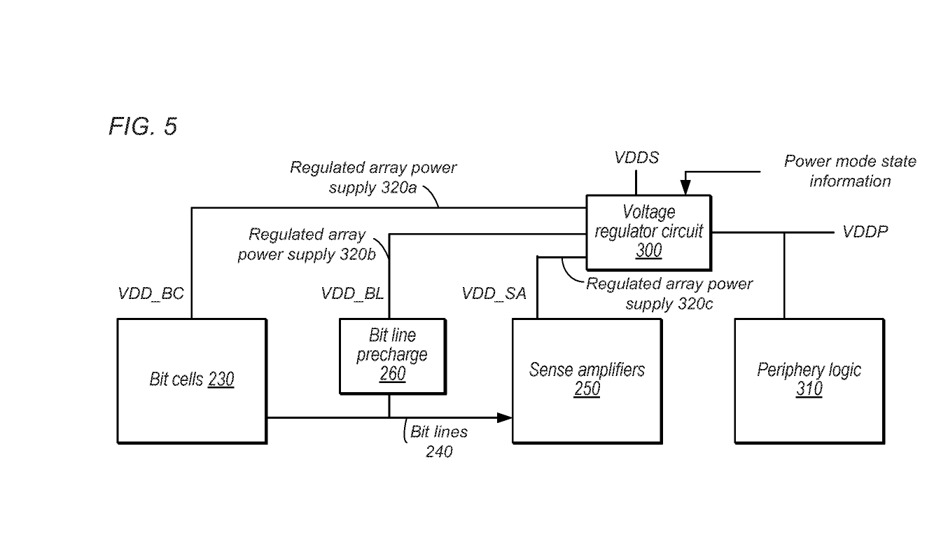

FIG. 5 illustrates a further embodiment of storage array 200. In the illustrated embodiment, voltage regulator circuit 300 is configured to generate multiple different regulated array power supplies 320a-c, each one coupled to a respective one of bit cells 230, bit line precharge circuit 260, and sense amplifiers 250. In this configuration, each of the regulated array power supplies 320a-c may be generated to operate at the threshold voltage of its corresponding element: VDD_BC for bit cells 230, VDD_BL for bit line precharge circuit 260, and VDD_SA for sense amplifiers 250. Generating multiple power supplies in this fashion may permit the various elements of storage array 200 to receive only the threshold voltage each requires, reducing unnecessary power consumption that may arise by driving an element at a higher voltage than is required to achieve a specified performance level.

FIG. 6 illustrates a possible configuration for voltage regulator circuit 300. In the illustrated embodiment, voltage regulator circuit 300 is coupled to produce regulated array power supply 320 and to receive array power supply VDDS and periphery power supply VDDP, as well as a set of control inputs denoted “S0-S3” and “override.” As shown here, voltage regulator circuit 300 includes control devices 610a-f as well as regulator devices 620a-c. As shown, control devices 610a-f are P-channel field effect transistors (PFETs), while regulator devices 620a-c are N-channel FETs (NFETs) that are coupled in a diode configuration, although any suitable type of device may be employed in either case.

In the illustrated embodiment, regulator devices 620a-c may be respectively designed to produce different levels of voltage drop across their source and drain. For example, varying the channel length of a FET may generally change its threshold voltage, thus increasing or decreasing the voltage drop across the device when it is coupled in a diode configuration as in FIG. 6. Thus, for example, if regulator devices 620a-c were designed to respectively produce voltage drops of 300, 500, and 700 millivolts, then the voltage of regulated array power supply 320 would be 300, 500, or 700 millivolts lower than the voltage applied to control devices 610d-f.

As shown, each of control devices 610a-f is controlled by a corresponding control input. These control inputs may correspond to the power mode state information that is received by voltage regulator circuit 300 as shown in FIGS. 3-5. Alternatively, the control inputs may be locally decoded from the power mode state information by other logic within voltage regulator circuit 300 or elsewhere.

Turning more specifically to the individual control inputs, control input S0 is coupled in a mutually exclusive manner to control devices 610a-b. Depending on the state of S0, either array power supply VDDS or periphery power supply VDDP is coupled as the power input to voltage regulator circuit 300. Control inputs S1-S3 then control which of regulator devices 610a-c the selected power supply passes through before emerging as regulated array power supply 320. The override control input may be employed to bypass the remainder of voltage regulator circuit 300 and unconditionally output array power supply VDDS as regulated array power supply 320. Providing this path may allow storage array 200 to selectively operate at full voltage, regardless of the power mode state information, which may be useful in the event that a manufacturing flaw or other defect prevents voltage regulator circuit 300 from operating as expected.

Excluding the override case, the particular configuration illustrated in FIG. 6 may permit five different possible sources for regulated array power supply 320: three based on periphery power supply VDDP, depending on which one of control inputs S1-S3 is selected, and two based on array power supply VDDS, depending on the state of control inputs S1-S2. However, not all possible state configurations of voltage regulator circuit 300 may be used in any given embodiment. Moreover, it is noted that the illustrated embodiment is merely one of numerous possibilities. Many variations in the number and configuration of control devices 610 and regulator devices 620 are possible and contemplated, which may support more or fewer possible voltage configurations than those shown in FIG. 6.

FIG. 7 illustrates another embodiment of voltage regulator circuit 300 that may be configured to generate multiple regulated array power supplies 320a-c, such as are shown in the configuration of FIG. 5. In the illustrated embodiment, voltage regulator circuit 300 includes control devices 610a-f and regulator devices 620a-c. The general principle of operation of this configuration is substantially similar to that of FIG. 6, except that each of regulated array power supplies 320a-c has fewer voltage options. In other embodiments, however, a greater degree of control complexity may be employed to provide more voltage options. For example, any or all of regulated array power supplies 320a-c could be selectively referenced to either array power supply VDDS or periphery power supply VDDP, and/or provide additional regulator devices 620 having different voltage characteristics.

The embodiments of voltage regulator circuit 300 discussed above may be referred to as passive voltage regulators. That is, while they may reliably reduce their input voltage by a selected amount to produce an output voltage, they may not include feedback paths of the sort used to actively raise or lower the regulated output voltage to meet a constant target. However, any suitable passive or active technique may be employed for voltage regulator circuit 300. For example, an operational amplifier may be employed within voltage regulator circuit 300 to provide active regulation according to any of numerous conventional regulator architectures.

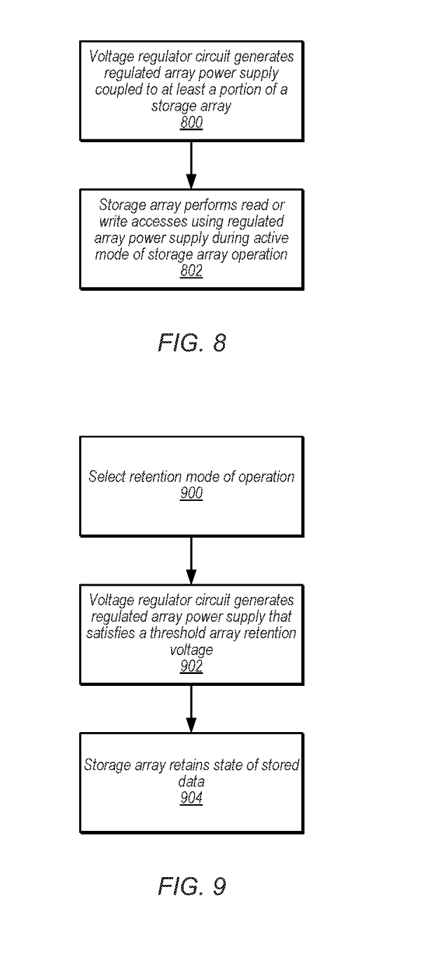

FIG. 8 is a flow chart illustrating an embodiment of a method of operation of a storage array that includes a voltage regulator circuit similar to those discussed above. Referring to FIG. 8 in conjunction with the previous figures, operation begins in block 800 where a voltage regulator circuit that is coupled to an array power supply and a periphery power supply generates a regulated array power supply that is coupled to at least a portion of a storage array. The storage array then performs read or write accesses using the regulated array power supply during an active mode of storage array operation (block 802).

In particular, generation of the regulated array power supply may be dependent on a selected one of several power modes of operation, as discussed above with respect to FIGS. 6-7. Moreover, the periphery power supply may selectively operate at any of several periphery operating voltages according to a respective power mode of operation. One or several of those periphery operating voltages may be less than a threshold array operating voltage required by the storage array for read or write access during the active mode of storage array operation. The regulated array power supply may be generated such that it operates at a voltage satisfying the threshold array operating voltage and being less than an operating voltage of the array power supply.

The foregoing discussion has primarily focused on the generation of a regulated array power supply that may be used during an active mode of storage array operation—i.e., a mode in which the state of data stored within storage array 200 may be accessed or changed using read or write operations. However, the foregoing techniques may also be applicable in the context of a retention mode of operation. In some embodiments, a retention mode of operation of storage array 200 may be a mode in which stored data is retained in its current state, but access to the stored data, e.g., via read or write operations, may be partially or totally unavailable. Retention mode may enable storage array 200 to operate at a lower voltage than an active mode of operation; in principle, if read and write operations are prohibited during retention mode, storage array 200 could be maintained at a minimum voltage necessary to allow bit cells 230 to maintain their state. Such a voltage, which may be referred to as a threshold array retention voltage, may be substantially lower than the threshold array operating voltage during an active state.

The threshold array retention voltage can be understood to be another voltage option that can be selected under a particular power mode of operation (e.g., a retention mode). As such, in some embodiments, voltage regulator circuit 300 may include an additional control input that is activated during retention mode via an additional control device 610. The additional control device 610 could be coupled to a regulator device 620 to generate the retention voltage in a manner similar to that discussed above with respect to FIG. 6. However, in some embodiments, the voltage of periphery power supply VDDP during retention mode may be used directly as the retention voltage without further modification. In such embodiments, the additional control device 610 could selectively couple periphery power supply VDDP directly to the regulated array power supply 320 output of voltage regulator circuit 300, without a need for an additional regulator device 620.

FIG. 9 illustrates an embodiment of a method of operation of a storage array that includes a voltage regulator circuit during a retention mode of operation. Referring to FIG. 9 in conjunction with the previous figures, operation begins in block 900 where a retention mode of operation is selected. For example, integrated circuit 100 could enter a low-power mode based on system inactivity or other factors, which could result in the various storage arrays 200 being placed in retention mode. A voltage regulator circuit that is coupled to an array power supply and a periphery power supply generates a regulated array power supply at a voltage that satisfies a threshold array retention voltage of the storage array (block 902). The storage array then retains the state of data stored within the storage array (block 904).

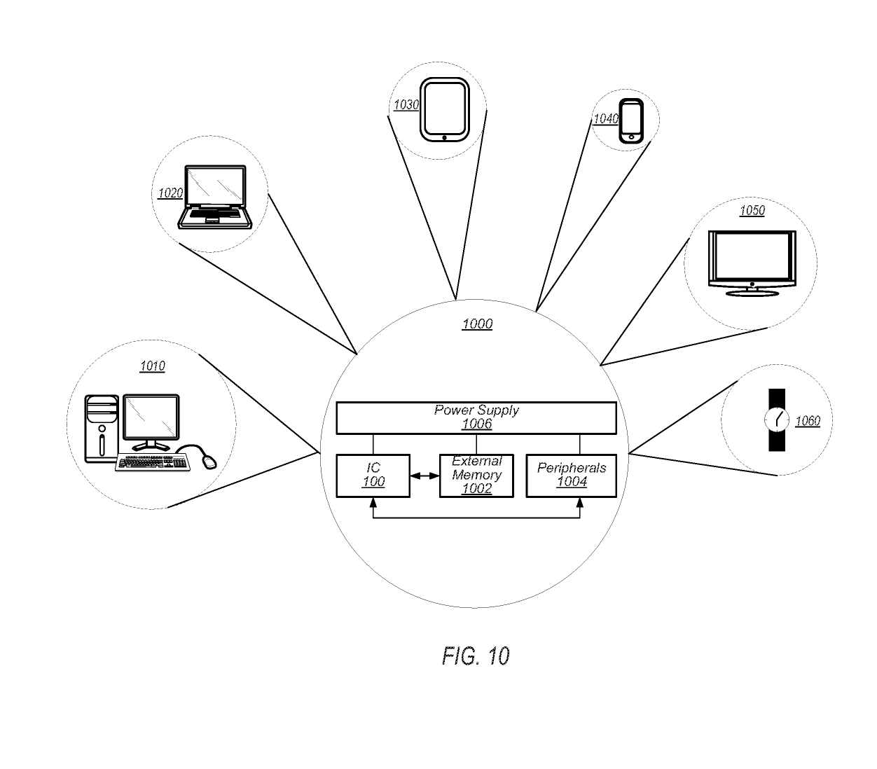

Referring next to FIG. 10, a block diagram of one embodiment of a system 1000 is shown. As shown, system 1000 may represent chip, circuitry, components, etc., of a desktop computer 1010, laptop computer 1020, tablet computer 1030, cell or mobile phone 1040, television 1050 (or set top box configured to be coupled to a television), wrist watch or other wearable item 1060, or otherwise. Other devices are possible and are contemplated. In the illustrated embodiment, the system 1000 includes at least one instance of processor 100 (of FIG. 1) coupled to an external memory 1002. In various embodiments, integrated circuit 100 may be a processor included within a system on chip (SoC) or larger integrated circuit (IC) which is coupled to external memory 1002, peripherals 1004, and power supply 1006.

Integrated circuit 100 is coupled to one or more peripherals 1004 and the external memory 1002. A power supply 1006 is also provided which supplies the supply voltages to processor 100 as well as one or more supply voltages to the memory 1002 and/or the peripherals 1004. In various embodiments, power supply 1006 may represent a battery (e.g., a rechargeable battery in a smart phone, laptop or tablet computer). In some embodiments, more than one instance of integrated circuit 100 may be included (and more than one external memory 1002 may be included as well).

The memory 1002 may be any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices may be coupled onto a circuit board to form memory modules such as single inline memory modules (SIMMs), dual inline memory modules (DIMMs), etc. Alternatively, the devices may be mounted with an SoC or IC containing integrated circuit 100 in a chip-on-chip configuration, a package-on-package configuration, or a multi-chip module configuration.

The peripherals 1004 may include any desired circuitry, depending on the type of system 1000. For example, in one embodiment, peripherals 1004 may include devices for various types of wireless communication, such as wifi, Bluetooth, cellular, global positioning system, etc. The peripherals 1004 may also include additional storage, including RAM storage, solid state storage, or disk storage. The peripherals 1004 may include user interface devices such as a display screen, including touch display screens or multitouch display screens, keyboard or other input devices, microphones, speakers, etc.

It should be emphasized that the above-described embodiments are only non-limiting examples of implementations. Numerous variations and modifications will become apparent to those skilled in the art once the above disclosure is fully appreciated. It is intended that the following claims be interpreted to embrace all such variations and modifications.

1. An integrated circuit, comprising:
a storage array including elements comprising a plurality of bit cells, a plurality of bit lines configured to read and write to ones of the plurality of bit cells, and a plurality of sense amplifiers coupled to the plurality of bit lines;
periphery logic coupled to the storage array; and
a voltage regulator circuit coupled to an array power supply and a periphery power supply, wherein the periphery power supply is configured to selectively operate at any of a plurality of periphery operating voltages according to a respective power mode of operation, and wherein one or more of the periphery operating voltages is less than a threshold array operating voltage required by the storage array for read or write access during an active mode of storage array operation;
wherein the voltage regulator circuit is configured to generate, dependent upon a selected power mode of operation, a regulated array power supply that operates at a voltage that satisfies the threshold array operating voltage and is less than an operating voltage of the array power supply, wherein the regulated array power supply is coupled to at least a portion of the storage array;
wherein two or more different ones of the elements within the storage array require different threshold voltages to operate during the active mode of storage array operation; and
wherein the regulated array power supply is one of a plurality of regulated array power supplies generated by the voltage regulator circuit that are respectively physically connected to the two or more different elements, wherein individual ones of the plurality of regulated array power supplies respectively satisfy corresponding ones of the different threshold voltages.

2. The integrated circuit of claim 1, wherein the regulated array power supply is coupled to the plurality of bit cells and the plurality of sense amplifiers, and is further coupled to a precharge circuit configured to precharge the plurality of bit lines.

3. The integrated circuit of claim 1, wherein the array power supply is coupled to the plurality of bit cells, and wherein the regulated array power supply is coupled to the plurality of sense amplifiers and is further coupled to a precharge circuit configured to precharge the plurality of bit lines.

4. The integrated circuit of claim 1:
wherein during a retention mode of operation, the storage array is configured to operate at a threshold array retention voltage that is sufficient to retain data stored in the storage array and is less than the threshold array operating voltage; and
wherein the voltage regulator circuit is further configured to selectively generate the regulated array power supply at a voltage that satisfies the threshold array retention voltage.

5. The integrated circuit of claim 4, wherein to selectively generate the regulated array power supply during the retention mode of operation, the voltage regulator circuit is further configured to selectively couple the periphery power supply to the storage array.

6. (canceled)

7. The integrated circuit of claim 1, wherein the voltage regulator circuit is coupled to receive a control input that, when active, causes the voltage regulator circuit to output the regulated array power supply at the operating voltage of the array power supply.

8. The integrated circuit of claim 1, wherein the storage array includes one or more elements that are coupled to the periphery power supply.

9. A system, comprising:
a memory; and
one or more processors coupled to the memory, each of the one or more processors including:
a storage array;
periphery logic coupled to the storage array; and
a voltage regulator circuit coupled to an array power supply and a periphery power supply, wherein the periphery power supply is configured to selectively operate at any of a plurality of periphery operating voltages according to a respective power mode of operation, and wherein one or more of the periphery operating voltages is less than a threshold array operating voltage required by the storage array for read or write access during an active mode of storage array operation;
wherein the voltage regulator circuit is configured to generate, dependent upon a selected power mode of operation, a regulated array power supply that operates at a voltage that satisfies the threshold array operating voltage and is less than an operating voltage of the array power supply, wherein the regulated array power supply is coupled to at least a portion of the storage array;
wherein two or more different elements within the storage array require different threshold voltages to operate during the active mode of storage array operation; and
wherein the regulated array power supply is one of a plurality of regulated array power supplies generated by the voltage regulator circuit that are respectively physically connected to the two or more different elements, wherein individual ones of the plurality of regulated array power supplies respectively satisfy corresponding ones of the different threshold voltages.

10. The system of claim 9, wherein the storage array is one of a plurality of storage arrays that exhibit different threshold operating voltage characteristics, wherein the voltage regulator circuit is one of a plurality of voltage regulator circuits corresponding respectively to the plurality of storage arrays, and for each given one of the plurality of storage arrays, a corresponding one of the plurality of voltage regulator circuits is configured to generate a respective regulated array power supply according to threshold operating voltage characteristics of the given storage array.

11. The system of claim 9, wherein the storage array corresponds to one or more of: a cache, a register file, or a buffer.

12. The system of claim 9, wherein the storage array includes a plurality of bit cells, a plurality of bit lines configured to read and write ones to of the plurality of bit cells, and a plurality of sense amplifiers coupled to the plurality of bit lines.

13. The system of claim 12, wherein the regulated array power supply is coupled to the plurality of bit cells and the plurality of sense amplifiers, and is further coupled to a precharge circuit configured to precharge the plurality of bit lines.

14. The system of claim 12, wherein the array power supply is coupled to the plurality of bit cells, and wherein the regulated array power supply is coupled to the plurality of sense amplifiers and is further coupled to a precharge circuit configured to precharge the plurality of bit lines.

15. The system of claim 9:
wherein during a retention mode of operation, the storage array is configured to operate at a threshold array retention voltage that is sufficient to retain data stored in the storage array and is less than the threshold array operating voltage; and
wherein the voltage regulator circuit is further configured to selectively generate the regulated array power supply at a voltage that satisfies the threshold array retention voltage.

16. The system of claim 15, wherein to selectively generate the regulated array power supply during the retention mode of operation, the voltage regulator circuit is further configured to selectively couple the periphery power supply to the storage array.

17. The system of claim 9:
wherein two or more different components within the storage array require different threshold voltages to operate during an active mode of storage array operation; and
wherein the regulated array power supply is one of a plurality of regulated array power supplies generated by the voltage regulator circuit, wherein individual ones of the plurality of regulated array power supplies respectively satisfy corresponding ones of the different threshold voltages.

18. A method, comprising:
generating, by a voltage regulator circuit coupled to an array power supply and a periphery power supply, a plurality of regulated array power supplies respectively coupled to two or more different elements of a storage array, wherein the two or more different elements of the storage array require different threshold voltages to operate during an active mode of storage array operation, and wherein:
the generating is dependent on a selected one of a plurality of power modes of operation; and
the periphery power supply selectively operates at any of a plurality of periphery operating voltages according to a respective one of the plurality of power modes of operation; and
performing, by the storage array, read or write accesses using the plurality of regulated array power supplies during the active mode of storage array operation, wherein:
one or more of the periphery operating voltages is less than a threshold array operating voltage required by the storage array for read or write access during the active mode of storage array operation; and
each of the regulated array power supplies operates at a voltage that respectively satisfies a corresponding one of the different threshold voltages and is less than an operating voltage of the array power supply.

19. The method of claim 18, wherein individual ones of the regulated array power supplies are respectively coupled to a plurality of bit cells of the storage array and a plurality of sense amplifiers of the storage array, and further coupled to a precharge circuit of the storage array that selectively precharges a plurality of bit lines.

20. The method of claim 18, wherein the array power supply is coupled to a plurality of bit cells of the storage array, and wherein individual ones of the regulated array power supplies are respectively coupled to a plurality of sense amplifiers of the storage array and to a precharge circuit of the storage array that selectively precharges a plurality of bit lines.
